(19) United States
(12) Patent Application Publication
(10) Pub. No.: US 2002/0197540 A1
(43) Pub. Date: Dec. 26, 2002

(54) Photosensitive flexographic device with associated thermally addressable mask

(75) Inventors: Jonathan William Goodin, Delta (CA); Cheng Yang, Burnaby (CA)

Correspondence Address: Mark A. Litman & Associates, P.A., York Business Center, Suite 205, 3209 West 76th St., Edina, MN, 55435, US

(73) Assignee: CreoScitex, Inc.

(21) Appl. No.: 09/803,541

(22) Filed: Mar. 9, 2001

(51) Int. Cl. G03F 1/06; G03F 1/00; G03F 7/095; G03F 7/11; G03F 7/38

(52) U.S. Cl. 430/5; 430/273.1; 430/306; 430/307; 430/327; 430/328; 430/944

(57) ABSTRACT

A photosensitive printing element is used for preparing flexographic printing plates. The photosensitive printing element comprises (a) a flexible support, (b) a photopolymerizable layer comprising an elastomeric composition sensitive to non-infrared actinic radiation, said layer being soluble, swellable or dispersible in a liquid developer prior to exposure to said non-infrared actinic radiation,and (c) at least one layer comprising an infrared radiation sensitive thermographic material which provides excellent image density (e.g., greater than 3.0) at least in the electromagnetic region of said non-infrared radiation sensitivity and preferably in both the visible and ultraviolet regions of the electromagnetic spectrum upon exposure to infrared laser radiation and thermal development. The mask may be on top of the elastomeric composition or underneath the elastomeric composition (where the flexible support is transparent).

### BACKGROUND OF THE INVENTION

1. FIELD OF THE INVENTION

This invention relates to a photosensitive element that is useful as a thermally developed masking element. In particular this invention relates to elements that have an integral masking layer.

2. BACKGROUND OF THE ART

Flexographic printing plates are a particular form of resist imageable material. Flexographic printing plates are generally used to form relief printing surfaces that find general use in letterpress printing, particularly on surfaces which are soft and easily deformable, such as packaging materials, e.g., cardboard, plastic films, etc. Flexographic printing plates can be prepared from photopolymerizable compositions, particularly flexible or elastomeric polymeric compositions including acrylic resins, urethane resins, epoxy resins, and the like including resins described in U.S. Pat. Nos. 4,323,637 and 4,427,749. The photopolymerizable compositions generally comprise an elastomeric binder, at least one monomer and a photoinitiator. Many photoresist elements such as flexographic imageable plates may have a photopolymerizable layer interposed between a support and a coversheet or multilayer cover element. Upon imagewise exposure of a negative-acting photosensitive medium to actinic radiation, polymerization, and hence, insolubilization of the photopolymerizable layer occurs in the exposed areas. Treatment with a suitable solvent removes the unexposed areas of the photopolymerizable layer, leaving a printing relief which can be used for flexographic printing. An alternative composition is described in U.S. Pat. No. 5,175,072 in which the flexographic printing plate does not require a liquid development step, but rather the unhardened composition is heated while in contact with an absorbent layer or sheet, and the unexposed photosensitive coating layer is softened and absorbed by the absorbant sheet. In this manner, there is no need for contacting the printing plates with solvents or having liquid effluent from the imaging process.

Imagewise exposure of a photosensitive element requires the use of a phototool or photomask which is a layer having imaging radiation transmissive (e.g., clear) and imaging radiation opaque areas that overlay the photopolymerizable layer. The phototool prevents exposure and polymerization of the photosensitive layer behind the opaque areas. The phototool allows exposure of the negative-acting photosensitive layer to radiation in the clear areas so that these areas polymerize and will remain on the support after the development step. The phototool is usually a photographic negative image (even a true photographic negative) of the desired printing image. If corrections are needed in the final image, a new negative usually must be made. This is a time-consuming and expensive process. In addition, the phototool may change slightly in dimensions due to changes in temperature and humidity. Thus, the same phototool, when used at different times or in different environments, may give different results and could cause registration problems between different layers (e.g., different color layers) applied to the final printed sheet. Thus, it would be desirable to eliminate the phototool by directly recording or writing information onto a photosensitive element, e.g., by means of a laser beam. The image to be formed on the photosensitive surface could be translated into digital information and the digital information used to place the laser spot for imaging on the photosensitive layer or surface. The digital information could even be transmitted from a distant location, as over fiber optic or electrical transmission systems. Corrections could be made easily and quickly by adjusting the digitized image prior to exposing a photosensitive element. In addition, the digitized image could be either positive or negative, eliminating the need to have both positive-working and negative-working photosensitive materials, or positive and negative phototools. This direct writing format of exposure saves storage space, provides greater convenience to the worker and, thus, reduces cost. Another advantage of direct writing or direct laser addressed exposure to a photosensitive surface is that registration can be precisely controlled by machine during the imaging step, while the physical placement of a phototool before flood exposure through the phototool introduces another variable into the location of the image on the photosensitive surface. Digitized imaging without a phototool also is particularly well-suited for making seamless, continuous printing forms. In general, it has not been very practical to use lasers to image the type of elements that are used to prepare flexographic printing plates. The elements have low photosensitivity and require long exposure times even with high-powered lasers. In addition, most of the photopolymerizable materials used in these elements have their greatest sensitivity in the ultraviolet range. While UV lasers are known, economical and reliable UV lasers with high power are generally not available. However, non-UV lasers that are relatively inexpensive, and which have a useful power output and which can be utilized to form a mask image on top of flexographic printing elements are commercially available.

A multilayer construction and method for preparing flexographic plates using a thermally ablated mask is described in U.S. Pat. No. 5,262,275 (Fan). This imageable construction has a disadvantage in that the laser energy needed to effect imaging is relatively high, requiring more than 1Joule/cm² and that the ablated materials can redeposit onto the areas to be exposed with U.V. light, reducing or filtering the exposing radiation and deteriorating image quality.

A multilayer image-recording material for producing relief images with infrared radiation of wavelengths greater than 1 micrometer is described in U.S. Pat. No. 4,555,471 (Barzynski et al). This material comprises a support bearing a near-UV photosensitive relief-forming layer, a transparent (e.g., U.V transparent or transmissive at the wavelengths needed for photosensitive layer exposure) intermediate layer, and a masking layer that undergoes a change in optical density (either an increase or decrease) when imaged with an infrared source (e.g., laser or diode) emitting at wavelengths greater than 1 micrometer. Such a recording material is processed by imagewise irradiation with an infrared laser, followed by flood-exposure with near-UV radiation. The masking and intermediate layers are then removed, and the relief-forming layer is developed in a conventional fashion, e.g., liquid wash or solution development. The disclosed masking layer is a film that is simply placed on top of or else laminated to the relief-forming layer either before or after the infrared imaging, and is then peeled away before subjecting the relief-forming layer to solution development. Another object of the invention is to use non-silver containing materials. Having the mask-forming layer as a separate film introduces problems to the system, particularly from dirt entrapment. The separate film mask layer also diminishes resolution and makes it difficult to maintain a precise relationship between the mask-forming layer and the underlying photosensitive layer(s). The examples in the Barzynski et al patent (noted above) also indicate that high energy is needed for using the disclosed multilayer image-recording material.

U.S. Pat. No. 5,493,327 (McCallum et al.) describes a method for making a newspaper printing plate or proofs on a polymeric film base. A photothermographic layer is exposed to a first wavelength to produce a thermally developable latent image. The thermographic latent image is developed by heat, which is used as a mask for subsequent exposure of a second Ultraviolet radiation photosensitive material. The photothermographic mask is exposed, developed and them brought into contact with the printing plate. It is not provided as an integral component of a separate functional imaging element, but was used as a portable mask, with all of the difficulties noted above with respect to silver halide or other masks.

### SUMMARY OF THE INVENTION

The present invention relates to a photosensitive printing element used for preparing flexographic printing plates comprising(a) a support, (b) a photopolymerizable layer comprising an elastomeric composition sensitive to non-infrared actinic radiation, said layer being soluble, swellable or dispersible in a liquid developer prior to exposure to said non-infrared actinic radiation,(c) at least one layer comprising an infrared radiation sensitive thermographic material which provides excellent image density (e.g., greater than 3.0) at least in the electromagnetic region of said non-infrared radiation sensitivity and preferably in both the visible and ultraviolet regions of the electromagnetic spectrum upon exposure to infrared laser radiation and thermal development.

The present invention also relates to a photosensitive printing element used for preparing flexographic printing plates comprising:

(a) a support,

(b) a photopolymerizable layer comprising an elastomeric binder, at least one monomer and an initiator having sensitivity to non-infrared actinic radiation, said layer being soluble, swellable or dispersible in a developer solution prior to exposure to actinic radiation or absorbable into a contacted absorbable surface or sheet when heated in contact with that absorbable surface or sheet,

(c) at least one layer of infrared radiation sensitive thermographic material which provides excellent image density in both the visible and ultra violet spectrum upon exposure to infrared laser radiation.

The invention further relates to a process for making a flexographic printing plate, which comprises:

(1) imagewise developing the layer (c) of the element described above with infrared laser radiation to form a mask;

(2) overall or flood exposing the photosensitive element to actinic radiation through the imaged mask; and

(3) imagewise removing portions of layer (b) and completely removing layer (c) to form a printing image.

This imagewise removing may be effected in any known manner, including for example either treating the product of step (2) with at least one developer solution to remove (i) the infrared-sensitive material which was not removed during step (1) and (ii) the areas of the photopolymerizable layer (b) which were not exposed to actinic radiation, or contacting said imagewise irradiated layer with an absorbent layer which can absorb the infra red sensitive material and the unirradiated flexographic composition when it has been heated to between 40° and 200° C., heating said composition layer so that it is at a temperature between 40° and 200° C. while in contact with said absorbent layer, said temperature being sufficiently high to enable said composition in unirradiated areas to flow into said absorbent layer, allowing at least 75% of composition from unirradiated areas in contact with said absorbent layer to be absorbed by said absorbent layer, and removing said absorbent layer and said at least 75% of composition from unirradiated areas from said flexible substrate wherein after said absorbent layer is removed from said flexible substrate, the absorbent layer is heated to soften and remove at least some of said composition from said absorbent layer.

### DETAILED DESCRIPTION OF THE INVENTION

A photosensitive printing element for preparing flexographic printing plates comprises at least the following layers in the order of (by the term “order of” is meant that the layers, with our without intermediate layers, such as antihalation layers, barrier layers, adhesion layers, etc., the layers recited appear in the order described):

(a) a support,

(b) a photopolymerizable layer comprising an elastomeric composition sensitive to non-infrared actinic radiation, the layer being soluble, swellable or dispersible in a liquid developer prior to exposure to the non-infrared actinic radiation,

(c) at least one layer comprising an infrared radiation sensitive thermographic material which provides an image density sufficient to slow, retard or prevent polymerization, usually an optical density of at least about 3.0 or greater at the wavelengths in the electromagnetic region of the non-infrared radiation sensitivity upon exposure to infrared laser radiation.

The photosensitive element may have layer (c) as at least one layer that provides a sufficicient image density when exposed to infrared radiation between about 700 and 1100, preferably between 750 and 850 nm at a fluence of 1.0 Joules/cm² (or less) for less than 1 minute.

Layer (c) may comprise a thermographic layer comprising a binder, a light-insensitive reducible silver source, and a reducing agent for silver ion. The reducible silver source may, for example, comprise a silver salt of a fatty acid.

An alternative way of describing this plate is as a photosensitive printing element for preparing flexographic printing plates comprising at least three layers in the order of:

(a) a support,

(b) a photopolymerizable layer comprising an elastomeric composition sensitive to non-infrared actinic radiation, said layer being soluble, swellable or dispersible in a liquid developer prior to exposure to said non-infrared actinic radiation,

(c) at least one layer comprising a thermographically imageable material that provides sufficient image density to prevent polymerization, usually greater than 3.0 at the wavelengths in the electromagnetic region of said non-infrared radiation sensitivity upon exposure to infrared laser radiation.

This type of photosensitive printing element preferably has layer (c) as removable from layer (b) by washing with liquid developer and scrubbing.

An alternative plate is a photosensitive printing element for preparing flexographic printing plates comprising at least three layers in the orders of:

(a) a transparent support,

(b) at least one layer comprising a thermographically imageable material that provides sufficient optical density to prevent polymerization, usually an image density greater than 3.0 at the wavelengths in the electromagnetic region of said non-infrared radiation sensitivity upon exposure to infrared laser radiation.

(c) a photopolymerizable layer comprising an elastomeric composition sensitive to non-infrared actinic radiation, said layer being soluble, swellable or dispersible in a liquid developer prior to exposure to said non-infrared actinic radiation; or

(a) a photopolymerizable layer comprising an elastomeric composition sensitive to non-infrared actinic radiation, said layer being soluble, swellable or dispersible in a liquid developer prior to exposure to said non-infrared actinic radiation

(b) a transparent support,

(c) at least one layer comprising a thermographically imageable material that provides sufficient optical density to prevent polymerization, usually an image density greater than 3.0 at the wavelengths in the electromagnetic region of said non-infrared radiation sensitivity upon exposure to infrared laser radiation.

In the latter two constructions, the flexographic composition is a topmost layer, and the exposing radiation for the flexographic layer is provided through the backside of the element, passing first through the backing, then the photothermographic mask layer or through the photothermographic masking layer and then the backing layer. This alternative format of construction is enabled because the layers are sensitive to different wavelengths of radiation, yet the benefits of the integral mask layer can still be provided in all of the construction. This type of photosensitive printing element preferably has layer (c) as removable from layer (b) by washing with liquid developer and scrubbing, although alternatively it may be removed by peeling the photothermographic masking layer from the photopolymerizable layer.

A process is also described according to the present invention for providing a flexible printing plate with a printing image thereon, the process comprising:

imagewise exposing the photosensitive printing element described above to an infrared radiation source of sufficient intensity to generate an image in layer (c), the image upon development having sufficient optical density to prevent polymerization, usually a maximum optical density (Dₘₐₓ) of at least 3.0, forming a mask image in layer (c);

exposing layer (b) with radiation that passes through image areas of layer (c) that allows transmission of non-infrared actinic radiation, and altering the solubility or dispersibility of layer (b) with respect to said liquid developer; and

developing said photosensitive printing element to form a printable image in layer (b) on said flexible substrate. This process may be performed where at least portions of layer (c) with an image thereon is removed from layer (b) after the exposing layer (b) but before developing the photosensitive printing element. For example, at least portions of layer (c) with an image thereon are removed from layer (b) at the same time as developing the photosensitive printing element. As a further example, at least portions of layer (c) with an image thereon are removed from layer (b) by the liquid developer at the same time that the liquid developer is used on layer (b).

A photosensitive printing element for preparing flexographic printing plates may be alternatively described as at least the following layers in the order of:

(a) a support,

(b) a photopolymerizable layer comprising an elastomeric composition sensitive to non-infrared actinic radiation, the layer being soluble, swellable or dispersible in a liquid developer prior to exposure to the non-infrared actinic radiation or absorbable in a porous medium when heated,

(c) at least one layer comprising an infrared radiation sensitive thermographic material which provides sufficient optical density to prevent polymerization, usually an image density greater than 3.0 at the wavelengths in the electromagnetic region of the non-infrared radiation sensitivity upon exposure to infrared laser radiation.

Alternatively the infra-red sensitive layer can be coated onto a clear support using the methods described above, and dried. A liquid photopolymerizable elastomeric composition is coated onto the infra-red sensitive layer and a further support applied to the topmost layer. The infra red sensitive layer is then imaged by laser. Then the light sensitive elastomeric layer is polymerized in the non-opaque areas of the mask. The bottom support is removed from the coating and the non-image areas of the elastomeric layer are removed by methods described earlier.

Additionally the thermosensitive material could be imaged prior to the application of the photopolymerizable elastomeric composition. In both methods the infrared sensitive layer should not be soluble or swellable in the elastomeric composition. The photosensitive element and process of the invention combine the convenience and sensitivity of infrared laser imaging with conventional photopolymerizable compositions to produce flexographic printing plates. The invention provides good printing quality quickly, economically, and with the capability of digital imaging means. The photosensitive element of the invention comprises, in order, a support, a photopolymerizable layer and a layer of infrared radiation sensitive material. The support can be any flexible material that is conventionally used with photosensitive elements used to prepare flexographic printing plates. Examples of suitable support materials include polymeric films such those formed by addition polymers and linear condensation polymers, transparent foams and fabrics. A preferred support is a flexible support, such as a polymeric support, and especially a polymeric film support such as polyester film; particularly preferred are polyethylene terephthalate and polyethylene naphthalate. A more rigid support can also be used. Examples of such are mild steel or aluminum. The support typically has a thickness from 2 to 10 mils (0.0051 to 0.025 cm), with a preferred thickness of 3 to 8 mils (0.0076 to 0.020 cm). As used herein, the term “photopolymnerizable” is intended to encompass systems that are photohardenable, photopolymerizable, photocrosslinkable, photoinsolubilizable or a combination of these. The photopolymerizable layer may comprise an elastomeric binder, at least one monomer and an initiator, where the initiator has a sensitivity to non-infrared actinic radiation. In most cases, the initiator may also be sensitive to visible or ultraviolet radiation. Any photopolymerizable compositions that are suitable for the formation of flexographic printing plates can be used for the present invention. Non-limiting examples of suitable compositions have been disclosed, for example, in Chen et al., U.S. Pat. No. 4,323,637, Gruetzmacher et al., U.S. Pat. No. 4,427,749, Feinberg et al., U.S. Pat. No. 4,894,315 and Martens U.S. Pat. No. 5,175,072. The elastomeric binder can be a single polymer or mixture of polymers that can be soluble, swellable or dispersible in aqueous, semi-aqueous or organic solvent developers, or absorbable into a porous sheet during heating of the composition. The term polymer is inclusive of polymers, oligomers, coplymers, terpolymers, tetrapolymers, graft polymers, block polymers and the like, and may be formed by any of the known polymerization mechanisms or materials. Binders that are soluble or dispersible in aqueous or semi-aqueous developers have been disclosed in Alles U.S. Pat. No. 3,458,311; Pohl U.S. Pat. No. 4,442,302; Pine U.S. Pat. No. 4,361,640; Inoue et al., U.S. Pat. No. 3,794,494; Proskow U.S. Pat. No. 4,177,074; Proskow U.S. Pat. No. 4,431,723; and Worns U.S. Pat. No. 4,517,279. Binders that are soluble, swellable or dispersible in organic solvent developers, and absorbable into a porous material include natural or synthetic polymers of conjugated diolefin hydrocarbons, including polyisoprene, 1,2-polybutadiene, 1,4-polybutadiene, butadiene/acrylonitrile, butadiene/styrene thermoplastic-elastomeric block copolymers and other copolymers. The block copolymers discussed in Chen U.S. Pat. No. 4,323,636; Heinz et al., U.S. Pat. No. 4,430,417; and Toda et al., U.S. Pat. No. 4,045,231 can be used. It is preferred that the binder be present in at least an amount of 65% by weight of the photosensitive layer. The term binder, as used herein, encompasses core shell microgels and blends of microgels and preformed macromolecular polymers, such as those disclosed in Fryd et al., U.S. Pat. No. 4,956,252.

Alternatively, as described by Martens, U.S. Pat. No. 5,175,072, the photopolymerizable layer can when contacting the image area with an absorbant layer which can absorb unirradiated composition when it has been heated to between 40° and 200° C., heating said composition layer so that it is at a temperature between 40° and 200° C. while in contact with said absorbent layer, said temperature being sufficiently high to enable said composition in unirradiated areas to flow into said absorbent layer, allowing at least 75% of said composition in unirradiated areas in contact with said absorbent layer to be absorbed by said absorbent layer, and removing said absorbent layer and said at least 75% of composition from unirradiated areas from said flexible substrate.

The photopolymerizable layer can contain a single monomer or mixture of monomers which must be compatible with the binder to the extent that a clear, non-cloudy photosensitive layer is produced. Monomers that can be used in the photopolymerizable layer are well known in the art. Examples of such monomers can be found in Chen U.S. Pat. No. 4,323,636; Fryd et al., U.S. Pat. No. 4,753,865; Fryd et al., U.S. Pat. No. 4,726,877; and Feinberg et al., U.S. Pat. No. 4,894,315. It is preferred that the monomer be present in at least an amount of 5% by weight of the photopolymerizable layer. The photoinitiator can be any single compound or combination of compounds which is sensitive to non-infrared actinic radiation, generating free radicals which initiate the polymerization of the monomer or monomers without excessive termination. The photoinitiator is generally sensitive to visible or ultraviolet radiation, preferably ultraviolet radiation. It should be thermally inactive at and below 185° C. Examples of suitable photoinitiators include the substituted and unsubstituted polynuclear quinones, onium salts (e.g., diaryliodonium salts, triarylsulfonium salts, s-triazines, biimidazoles, photosensitive complexed metals and the like. Examples of suitable systems have been disclosed in Gruetzmacher U.S. Pat. No. 4,460,675 and Feinberg et al., U.S. Pat. No. 4,894,315. Photoinitiators are generally present in amounts from 0.001% to 10.0% based on the weight of the photopolymerizable composition. The photopolymerizable layer can contain other additives depending on the final properties desired. Such additives include sensitizers, rheology modifiers, thermal polymerization inhibitors, tackifiers, plasticizers, colorants, antihalation materials, acutance dyes, antioxidants, antiozonants, or fillers. The thickness of the photopolymerizable layer can vary over a wide range depending upon the type of printing plate desired. For so called “thin plates” the photopolymerizable layer can be from about 20 to 50 mils (0.05 to 0.13 cm) in thickness. Thicker plates will have a photopolymerizable layer up to 100-250 mils (0.25 to 0.64 cm) in thickness or greater. A barrier layer may be used as part of the construction when it is a barrier layer that is soluble, swellable or dispersible in the developer solvent prior to exposure to actinic radiation, but is not affected by the developer solvent after exposure to actinic radiation. When this type of barrier layer is used, the barrier layer is removed by developer solvent only in those areas that are not exposed to actinic radiation. The barrier layer that has been exposed to actinic radiation remains on the surface of the polymerized areas of the photopolymerizable layer and becomes the actual printing surface of the printing plate. This type of barrier layer can be photosensitive itself, i.e., contain monomer and initiator, or it can become photosensitive when in contact with the photopolymerizable layer. This second type of barrier layer is usually a layer of an elastomeric composition. The composition can comprise simply of a non-photosensitive elastomeric binder layer similar to the binder in the photopolymerizable layer or it can be the binder in combination with a monomer and initiator. A preferred barrier layer is an elastomeric composition comprising an elastomeric polymeric binder, a second polymeric binder and optionally a non-migratory dye or pigment. The elastomeric polymeric binder in the elastomeric composition is generally the same as or similar to the elastomeric binder present in the photopolymer layer. Suitable compositions for the barrier layer are those disclosed as elastomeric compositions in the multilayer cover element described in Gruetzmacher et al., U.S. Pat. Nos. 4,427,759 and 4,460,675. The barrier layer, of either type, should be thick enough to act as an effective barrier to prevent migration and air permeation and also be thin enough to minimize its effect on the exposure of the photopolymerizable layer to actinic radiation. In general, the barrier layer will have a thickness in the range of 0.01 to 3 mils (0.00025 to 0.076 mm). A preferred thickness range is 0.015 to 2.5 mils (0.00038 to 0.064 mm) and should be transparent or highly transmissive of the imaging radiation. Over the flexographic plate or barrier layer (“over” meaning between the flexographic composition and the source of flexographic irradiation), there is at least one layer of infrared radiation sensitive material that is thermographic and becomes opaque to ultra violet and visible light. The preferred thermographic material comprises a generally light insensitive silver salt; a suitable reducing agent for silver ion; a binder material and an infrared radiation-absorbing compound. Such thermographic materials are described in WO 96/10213 and U.S.Pat. No. 5,840,469. The properties of the infrared-sensitive layer can be modified by using other ingredients, such as, for example plasticizers surfactants, and coating aids, provided that they do not adversely affect the imaging properties of the element. The infrared-absorbing material should have a strong absorption in the region of the imaging radiation, typically 700 to 1100 nm Examples of suitable infrared-absorbing materials include, poly(substituted)phthalocyanine compounds; cyanine dyes; squarylium dyes; chalcogenopyryloarylidene dyes; bis(chalcogenopyrylo)polymethine dyes; oxyindolizine dyes; bis(aminoaryl)polymethine dyes; merocyanine dyes; croconium dyes; metal thiolate dyes; and quinoid dyes.

The light-insensitive metal salts are materials that in the presence of a reducing agent undergo reduction at elevated temperatures, e.g., about 60° to 250° C., to form silver metal. Non-limiting examples of silver salts of aliphatic carboxylic acids include silver behenate, silver stearate, silver oleate, silver erucate, silver laurate, silver caproate, silver myristate, silver palmitate, silver maleate, silver lumarate, silver tartarate, silver linoleate, silver camphorate, and mixtures thereof Complexes of organic or inorganic silver salts wherein the ligand has a gross stability constant between 4.0 and 10.0 can also be used. Silver sats of aromatic carboxylic acids and other carboxyl group containing compounds include silver benzoate, substituted silver benzoates such as silver 3,5-dihydroxybenzoate, silver o-methylbenzoate, silver m-methylbenzoate, silver p-methylbenzoate, silver 2,4-diclilorobenzoate, silver acetamidobenzoate, silver p-phenyl benzoate, silver phthalate, silver terephthalate, silver salicylate, silver phenylacetate, silver pyromellitate, silver salts of 3-carboxymethyl-4-methyl-4-thiazoline-2-thiones or the like as described in U.S. Pat. No. 3,785,830, and silver salts of aliphatic carboxylic acids containing a thioether group as disclosed in U.S. Pat. No. 3,330,663.

Silver salts of compounds containing mercapto or thione groups and derivatives thereof can also be used. Preferred examples of these compounds include silver 3-mercapto-4-phenyl-1,2,4-triazolate, silver 2-mercaptobenzimidazolate, silver 2-mercapto-5-aminothiadiazolate, silver 2-(S-ethylglycolamido)benzothiazolate; silver salts of thioglycolic acids such as silver salts of S-alkyl thioglycolic acids wherein the alkyl group has from 12 to 22 carbon atoms; silver salts of dithiocarboxylic acids such as silver dithioacetate, silver thioamidoate, silver 1-methyl-2-phenyl-4-thiopyridine-5-carboxylate, silver triazinethiolate, silver 2-sulfidobenzoxazole; and silver salts as disclosed in U.S. Pat. No. 4,123,274, which is incorporated herein by reference. Furthermore, silver salts of a compound containing an amino group can be used. Examples of these compounds include silver salts of benzotriazoles, such as silver benzotriazolate; silver salts of alkyl-substituted benzotriazoles such as silver methylbenzotriazolate, etc.; silver salts of halogen-substituted benzotriazoles such as silver 5-chlorobenzotriazolate, etc.; silver salts of carboimidobenzotriazoles, etc.; silver salts of 1,2,4-triazoles and 1-H-tetrazoles as described in U.S. Pat. No. 4,220,709; silver salts of imidazoles; and the like. The concentration of the thermographic developed silver material is chosen so as to achieve the desired optical density, i.e., so that the layer prevents the transmission of actinic radiation to the photopolymerizable layer. In general, a transmission optical density greater than 2.0 is preferred. The concentration of thermographic developed silver material which is needed, decreases with increasing thickness of the layer. Preferably, the light-insensitive silver salt material is present in an amount of about 5 to 60% by weight and more preferably, from about 30 to 50% by weight, based upon the total weight of the thermographic silver emulsion layer. The reducing agent in the thermographic imaging system provides improved image density at the short exposure times found when the thermographic media is heated using an infrared laser. In general, the thermographic element of the invention can provide an image of superior sharpness and density when exposed to an infrared laser at a sufficient intensity and for a sufficient time to provide total energy of about 250 to 650 mJ/cm². The total energy delivered will depend on a variety of factors known to those of skill in the art, such as laser power, the size of the spot created by the laser on the imaging plane, the time of exposure, and so on. Notably, superior images can be obtained with very short exposure times, i.e. about 10 microseconds or less. Under conditions sufficient to provide total energy of about 300 to 500 mJ/cm², the thermographic element of the invention can provide a sharp image of a spot as small as 5 micrometers. The thermographic element of the invention, containing reducing agent, generally has a Dₘᵢₙ in the ultraviolet range (365 to 410 nm) of less than about 0.2, preferably less than about 0.15 and a Dₘₐₓ in the ultraviolet range of greater than about 2.5, preferably greater than about 3.0. The reducing agent is present in an amount of about 5 to 25 wt%, preferably about 10 to 20 wt% based on the total weight of the thermographic silver emulsion layer. Auxiliary reducing agents or development accelerators that are known in the art may be optionally included in the thermographic silver emulsion layer depending upon the silver source used.

When used in black-and-white thermographic elements, the reducing agent for the organic silver salt may be any compound, preferably organic compound, that can reduce silver ion to metallic silver. Conventional photographic developers such as phenidone, hydroquinones, and catechol are useful, but hindered bisphenol reducing agents are preferred.

A wide range of reducing agents has been disclosed in dry silver systems (for both thermographic and photothermographic media) including amidoximes, such as phenylamidoxime, 2-thienylamidoxime and p-phenoxy-phenylarnidoxime; azines, such as 4-hydroxy-3,5-dimethoxybenzaldehydeazine; a combination of aliphatic carboxylic acid aryl hydrazides and ascorbic acid, such as 2,2′-bis(hydroxymethyl)propionyl-β-phenylhydrazide in combination with ascorbic acid; a combination of polyhydroxybenzene and hydroxylamine; a reductone and/or a hydrazine, such as a combination of hydroquinone and bis(ethoxyethyl)hydroxylamine, piperidinohexose reductone, or formyl-4-methylphenylhydrazine; hydroxamic acids, such as phenylhydroxamic acid, p-hydroxyphenylhydroxamic acid, and o-alaninehydroxamic acid; a combination of azines and sulfonamidophenols, such as pheno-thiazine with p-benzenesulfonamidophenol or 2,6-dichloro-4-benzenesulfonamidophenol; α-cyanophenylacetic acid derivatives, such as ethyl α-cyano-2-methylphenylacetate, ethyl α-cyano-phenylacetate; a combination of bis-o-naphthol and a 1,3-dihydroxybenzene derivative, such as 2,4-dihydroxybenzophenone or 2,4-dihydroxyacetophenone; 5-pyrazolones such as 3-methyl-1-phenyl-5-pyrazolone; reductones, such as dimethylaminohexose reductone, anhydro-dihydroaminohexose reductone, and anhydrodihydro-piperidone-hexose reductone; sulfonamido-phenol reducing agents, such as 2,6-dichloro-4-benzenesulfonamidophenol and p-benzene-sulfonamidophenol; indane-1,3-diones, such as 2-phenylindane-1,3-dione; chromans, such as 2,2-dimethyl-7-t-butyl-6-hydroxychroman; 1 ,4-dihydropyridines, such as 2,6-dimethoxy-3,5-dicarbethoxy-1,4-dihydropyridine; ascorbic acid derivatives, such as 1-ascorbylpalmitate, ascorbylstearate; unsaturated aldehydes and ketones; certain 1,3-indanediones, and 3-pyrazolidones (phenidones).

Hindered bisphenol developers are compounds that contain only one hydroxy group on a given phenyl ring and have at least one additional substituent located ortho to the hydroxy group. They differ from traditional photographic developers which contain two hydroxy groups on the same phenyl ring (such as is found in hydroquinones). Hindered phenol developers may contain more than one hydroxy group as long as they are located on different phenyl rings. Hindered phenol developers include, for example, binaphthols (i.e., dihydroxybinaphthyls), biphenols (i.e., dihydroxybiphenyls), bis(hydroxynaphthyl)methanes, bis(hydroxyphenyl)methanes, hindered phenols, and naphthols.

Non-limiting representative bis-o-naphthols, such as by 2,2′-dihydroxyl--binaphthyl, 6,6′-dibromo-2,2′-dihydroxy- 1,1′-binaphthyl, and bis(2-hydroxy-1-naphthyl)methane. For additional compounds see U.S. Pat. No. 5,262,295 at column 6, fines 12-13, incorporated herein by reference.

Non-limiting representative bisphenols include 2,2′-dihydroxy-3,3′-di-t-butyl-5,5-dimethylbiphenyl; 2,2′-dihydroxy-3,3′,5,5′-tetra-t-butylbiphenyl; 2,2′-dihydroxy-3,3′-di-t-butyl-5,5′-dichlorobiphenyl; 2-(2-hydroxy-3-t-butyl-5-methylphenyl)-4-methyl-6-n-hexylphenol; 4,4′-dihydroxy-3,3′,5,5′-tetra-t-butylbiphenyl; and 4,4′-dihydroxy-3,3′,5,5′-tetramethylbiphenyl. For additional compounds see U.S. Pat. No. 5,262,295 at column 4, lines 17-47, incorporated herein by reference.

Non-limiting representative bis(hydroxynaphthyl)methanes include 2,2′-methylene-bis(2-methyl-1-naphthol)methane. For additional compounds see U.S. Pat. No. 5,262,295 at column 6, lines 14-16, incorporated herein by reference.

Non-limiting representative bis(hydroxyphenyl)methanes include bis(2-hydroxy-3-t-butyl-5-methylphenyl)methane (CAO-5); 1,1-bis(2-hydroxy-3,5-dimethylphenyl)-3,5,5-trimethylhexane (Permanax® or Nonox®); 1,1′-bis(3,5-tetra-t-butyl-4-hydroxy)methane; 2,2-bis(4-hydroxy-3-methylphenyl)propane; 4,4-ethylidene-bis(2-t-butyl-6-methylphenol); and 2,2-bis(3,5-dimethyl-4-hydroxyphenyl)propane. For additional compounds see U.S. Pat. No. 5,262,295 at column 5 line 63 to column 6, line 8 incorporated herein by reference.

Non-limiting representative hindered phenols include 2,6-di-t-butylphenol; 2,6-di-t-butyl-4-methylphenol; 2,4-di-t-butylphenol; 2,6-dichlorophenol; 2,6-dimethylphenol; and 2-t-butyl-6-methylphenol.

Non-limiting representative hindered naphthols include 1-naphthol; 4-methyl-1-naphthol; 4-methoxy-1-naphthol; 4-chloro-1-naphthol; and 2-methyl-1-naphthol. For additional compounds see U.S. Pat. No. 5,262,295 at column 6, lines 17-20, incorporated herein by reference.

The reducing agent should be present as 1 to 15 % by weight of the imaging layer. In multilayer elements, if the reducing agent is added to a layer other than an emulsion layer so that they migrate into the organic silver salt layer during development, slightly higher proportions, of from about 2 to 20 %, tend to be more desirable.

Thermographic elements of the invention may contain contrast enhancers, co-developers or mixtures thereof. For example, the trityl hydrazide or formyl phenylhydrazine compounds described in U.S. Pat. No. 5,496,695 may be used; the amnine compounds described in U.S. Pat. No. 5,545,505 may be used; hydroxamic acid compounds described in U.S. Pat. No. 5,545,507 may be used. The acrylonitrile compounds described in U.S. Pat. No. 5,545,515 may be used; the N-acyl-hydrazide compounds as described in U.S. Pat. No. 5,558,983 may be used; the 2-substituted malondialdehyde compounds described in U.S. patent application Ser. No. 08/615,359 (filed Mar. 14, 1996); the 4-substituted isoxazole compounds described in U.S. patent application Ser. No. 08/615,928 (filed Mar. 14, 1996); the 3-heteroaromatic-substituted acrylonitrile compounds described in U.S. patent application Ser. No. 08/648,742 (filed May 16, 1996); and the hydrogen atom donor compounds described in U.S. patent application Ser. No. 08/530,066 (filed Sep. 19, 1995) may be used;

Further, the reducing agent may optionally comprise a compound capable of being oxidized to form or release a dye. Preferably the dye-forming material is a leuco dye.

Thermographic elements of the invention may also contain other additives such as shelf-life stabilizers, toners, development accelerators, acutance dyes, post-processing stabilizers or stabilizer precursors, and other image-modifying agents.

The thermographic imaging elements of the present invention are not light-sensitive in the traditional sense and therefore should not contain excessive photosensitive agents such as silver halides, photoinitiators, or photogenerated bleaching agents. Excessive amounts of these agents will result in an undesirable increase in Dₘᵢₙ upon light exposure. Light stabilizers such as benzotriazole, phenylmercaptotetrazole, and other light stabilizers known in the art may be added to the thermographic silver emulsion. The preferred light stabilizer is benzotriazole. The light stabilizer should preferably be present in an amount in the range of about 0.1 to 3.0 wt% of the thermographic silver emulsion layer and more preferably, from 0.3 to 2.0 wt. %, based on the total weight of the thermographic silver emulsion.

The thermographic silver emulsion layer(s) found in the present invention also may employ and preferably does employ a binder. The binder is a polymeric material which should satisfy several requirements: (1) The binder should be removable from the surface of the photopolymerizable layer after the imaging of the flexographic plate. This condition is met if the binder is soluble, swellable or dispersible in the developer solvent for the photopolymerizable layer. The binder may also be removed in a separate step, e.g., the binder can be soluble, swellable or dispersible in a second solvent that does not affect the polymerized areas of the photopolymerizable layer. (3) The binder should be one in which the other materials in the infrared-sensitive layer can be uniformly dispersed. (4) The binder should be capable of forming a uniform coating on the flexographic printing surface. Any conventional polymeric binder known to those skilled in the art can be utilized. For example, the binder may be selected from many of the well-known natural and synthetic resins such as gelatin, polyvinyl acetals, polyvinyl chloride, polyvinyl acetate, cellulose acetate, polyolefins, polyesters, polystyrene, polyacrylonitrile, polycarbonates, and the like. Copolymers and terpolymers are, of course, included in these definitions, examples of which, include, but are not limited to, the polyvinyl aldehydes, such as polyvinyl acetals, polyvinyl butyrals, polyvinyl formals, styrene/maleic anhydride copolymers, and vinyl copolymers. Polyvinyl acetate and polyvinyl butyral are preferred resins. Preferably, the binder should be present in an amount in the range of about 10 to 60 wt.% and more preferably about 15 to 40 wt.% based upon the total weight of the thernographic silver emulsion layer.

A plasticizer can be added to adjust the film forming properties of the binder. The plasticizer should be present in an amount effective for the intended purpose which depends on the properties of the binder, the plasticizer, and the other components of the layer. In general, the amount of plasticizer, when present, is 1-25% by weight, and more preferably 2-15% based on the weight of the layer.

The thickness of the infrared-sensitive layer should be in a range to optimize both sensitivity and opacity. The layer should be thin enough to provide good sensitivity. At the same time, the layer should be thick enough so that the opacified areas of the layer after imagewise exposure effectively mask the photopolymerizable layer from actinic radiation. In general, this layer will have a thickness from about 1 micrometre to about 35 micrometers. It is preferred that the thickness be from 2 micrometres to 25 micrometers.

The photosensitive element of the invention is generally prepared by first preparing the photopolymerizable layer on the support and then applying the infrared-sensitive layer by coating, adhering or lamination techniques. The photopolymerizable layer itself can be prepared in many ways by admixing the binder, monomer, initiator, and other ingredients. It is preferred that the photopolymerizable mixture be formed into a hot melt and then calendered to the desired thickness. An extruder can be used to perform the functions of melting, mixing, deaerating and filtering the composition. The extruded mixture is then calendered between the support and a temporary coversheet or a temporary coversheet that has been previously coated with the barrier layer. In the latter case it is arranged so that the barrier layer is next to the photopolymerizable layer during the calendering process. The adhesion between the barrier layer and the temporary coversheet should be low, so that the barrier layer will remain intact on the photopolymerizable layer when the temporary coversheet is removed. The layer may be applied by any convenient method, including, but not limited to, extrusion coating, bar coating, wire wound rod coating, screen coating, curtain coating, die slot coating, meniscus coating, roller coating or gravure coating.

The infrared-sensitive layer is generally applied using any known coating technique, particularly methodologies that do not require elevated temperatures, including spray coating, extrusion coating, bar coating, wire wound rod coating, screen coating, curtain coating, die slot coating, meniscus coating, roller coating or gravure coating. The element is prepared by removing the coversheet from the photopolymerizable layer or the printable barrier layer on the photopolymerizable layer, the infra red sensitive layer is then sprayed or coated onto this and dried prior to laser imaging.

The infrared-sensitive layer can be prepared also by coating the infrared-sensitive material onto a second temporary coversheet. In this case, the final element is prepared by (1) removing the temporary coversheet from the photopolymerizable layer and placing it together with the second element (second temporary coversheet/infrared-sensitive layer.) This composite element is then pressed together with moderate pressure. The second temporary coversheet can remain in place for storage, but must be removed prior to IR laser imaging.

Alternatively, the two layers can all be prepared on temporary coversheets: the photopolymerizable layer by extrusion and calendering or pressing in a mold; and the infrared-sensitive layer by coating. The final element is prepared by removing the temporary coversheet from the photopolymerizable element, applying the barrier layer such that the barrier layer is adjacent to the photopolymerizable layer, removing the temporary coversheet from the barrier layer, and applying the infrared-sensitive layer such that the infrared-sensitive layer is adjacent to the barrier layer. The composite structure is laminated together as each new layer is added or one time for all the layers. The temporary coversheet on the infrared-sensitive layer can remain in place for storage, but must be removed prior to imaging. The process of the invention involves:

(1) imagewise thermographically developing the infra red sensitive layer (d) of the element described above to form a mask; during the thermographic step, material in the infrared-sensitive layer is developed and rendered opaque (at least an optical density of 3.0 to the electromagnetic radiation to which the photosensitive layer is sensitive), in the areas exposed to the infrared laser radiation. The areas exposed to laser radiation in the infrared-sensitive layer correspond to the areas of the photopolymerizable layer which will be washed out in the formation of the final printing plate.

(2) overall exposing (referred to as flood exposing) the mask and thereby exposing those areas of the photosensitive element to actinic radiation where the exposing radiation penetrates through transmissive regions of the mask to form a product comprising the mask over an imagewise exposed photosensitive layer (e,g, the photosensitive layer having effectively a latent image from the exposure); and

(3) treating the product of step (2) with at least one developer solution treating the product of step (2) with at least one developer solution to remove all of or part of (i) the infrared-sensitive layer (and optionally or preferably all of the regions of the infrared sensitive layer, including those that have been developed to opacity and those areas that have not been developed to opacity by thermal treatment, (ii) the areas of the optional barrier layer which were not exposed to actinic radiation, and (iii) the areas of the photopolymerizable layer (b) which were not exposed to actinic radiation.

The first step in the process of the invention is to image the thermographic layer (d) to form a mask. This exposure is given to the side of the photosensitive element bearing the infrared-sensitive layer. Although laser address of the thermographic layer is preferred, the layer may be addressed by thermal printing with a printing head with appropriate selection of properties on the surface of the thermographic layer to avoid sticking of the head to the layer. If a temporary coversheet is present in the element, it can optionally be removed prior to the exposure step, or left on during exposure if the temporary cover sheet is transmissive to infrared radiation. The exposure can be carried out using various types of infrared lasers. Diode lasers emitting in the region of 750 to 880 nm offer substantial advantages in terms of their small size, low cost, stability, reliability, ruggedness and ease of modulation, but any infrared radiation (e.g., up to 1200 nm) may be used with appropriate sensitization of the layer. Diode lasers emitting in the range of 780 to 850 nm may be used to advantage. Such lasers are commercially available from, for example, Spectra Diode Laboratories (San Jose, Calif.). YAG lasers emitting at about 1064 nm are also very effective. The next step in the process of the invention is to overall expose the mask to imagewise expose the photosensitive element to actinic radiation through the radiation transparent or transmissive areas of the mask. The type of radiation used is dependent on the type of sensitivity in the photopolymerizable layer, which tends to be dependent upon the particular photoinitiator in the photopolymerizable layer. The radiation-opaque material created by the imaging/development process in the infrared sensitive layer that remains on top of the barrier layer on the photopolymerizable layer prevents the material beneath areas that have developed an opacity from the thermographic imaging process from being exposed to the radiation and hence those areas covered by the radiation-opaque material do not polymerize. The areas not covered by the radiation-opaque material that have developed an opacity from the thermographic imaging process are exposed to actinic radiation and polymerize. Any conventional sources of actinic radiation can be used for this exposure step. Examples of suitable visible or UV sources include carbon arcs, mercury-vapor arcs, fluorescent lamps, electron flash units, electron beam units and photographic flood lamps. The most suitable sources of UV radiation are the mercury-vapor lamps, particularly the sun lamps. A standard radiation source is the Sylvania 350 Blacklight fluorescent lamp (FR 48T12/350 VL/VHO/180, 115 w) which has a central wavelength of emission around 365 nm. Lasers, such as excimer lasers, may be used for an exposure over the entire surface of the photomask, but that is not the preferred mechanism at this time. It is contemplated that the imagewise exposure to infrared radiation and the overall exposure of the phototool to actinic radiation can be carried out in the same equipment. It is preferred that this be done using a drum supporting system for the medium, i.e., the photosensitive element is mounted on a drum which is rotated to allow for exposure of different areas of the element. The drum rotates and the exposing system raster scans across the rotating surface of the element, either while the drum is rotating (preferred) or during sequential position stops in the rotation of the drum. The actinic radiation exposure time for exposing the entire thermographic layer or the photosensitive layer on the element can vary from a few seconds to minutes, depending upon the intensity and spectral energy distribution of the radiation, its distance from the photosensitive element, and the nature and amount of the photopolymerizable composition. Typically for the exposure of the photothermographic layer, a mercury vapor arc or a sunlamp is used at a distance of about 0.5 to about 60 inches (1.25 to 153 cm) from the photosensitive element. Exposure temperatures are preferably ambient or slightly higher, i.e., about 20° to about 35° C. The process of the invention usually includes a back exposure or backflash step on the photosensitive layer to harden the floor of the photosensitive layer. This is a blanket exposure to actinic radiation through the support (which should therefore be transmissive of radiation to which that layer is photosensitive). It is used to create a shallow layer of polymerized material, or a floor, on the support side of the photopolymerizable layer and to assist in sensitizing the photopolymerizable layer. The floor provides improved adhesion between the photopolymerizable layer and the support, helps highlight dot resolution and also establishes the depth of the plate relief. The backflash exposure can take place before, after or during the other imaging steps. It is preferred that the backflash take place just prior to the imagewise exposure to infrared laser radiation on the infrared-sensitive layer side of the element. Any of the conventional radiation sources discussed above can be used for the backflash exposure step. Exposure time generally range from a few seconds up to about a minute. Following overall exposure to UV radiation through the mask formed by the actinic radiation-opaque material, the image is developed by washing with a suitable developer. Development is usually carried out at about room temperature. The developers can be organic solvents, aqueous or semi-aqueous solutions. The choice of the developer will depend on the chemical nature of the photopolymerizable material to be removed. Suitable organic solvent developers include aromatic or aliphatic hydrocarbon and aliphatic or aromatic halohydrocarbon solvents, or mixtures of such solvents with suitable alcohols. Other organic solvent developers have been disclosed in published German Application 38 28 551. Suitable semi-aqueous developers usually contain water and a water miscible organic solvent and an alkaline material. Suitable aqueous developers usually contain water and an alkaline material. Other suitable aqueous developer combinations are described in U.S. Pat. No. 3,796,602. Development time can vary, but it is preferably in the range of about 2 to 25 minutes. Developer can be applied in any convenient manner, including immersion, spraying and brush or roller application Brushing aids can be used to remove the unpolymerized portions of the composition. However, washout is frequently carried out in an automatic processing unit that uses developer and mechanical brushing action to removed the unexposed portions of the plate, leaving a relief constituting the exposed image and the floor. A pre-development step may be necessary if the infrared-sensitive layer is not removable by the developer solvent. An additional developer, which does not effect the polymerized photosensitive material can be applied to remove the infrared-sensitive layer first.

The infra red sensitive layer could also be removed by peeling if it is covered by an additional support.

Following solvent development, the relief printing plates are generally blotted or wiped dry, and then dried in a forced air or infrared oven. Drying times and temperatures may vary, however, typically the plate is dried for 60 to 120 minutes at 60 C. High temperatures are not recommended because the support can shrink and this can cause registration problems.

Alternatively, the photopolymerisable layer can be developed according to the method of Martens U.S. Pat. No. 5,175,072. Contacting the imagewise irradiated composition with an absorbent layer which can absorb the infra-red layer and the unirradiated photohardenable composition when it has been heated between 40 degrees C. and 200 degrees C. That temperature is sufficiently high to enable the composition into the absorbent layer followed by removal of the absorbent material and the material absorbed into it, revealing an image.

Most flexographic printing plates are uniformly post-exposed to ensure that the photopolymerization process is complete and that the plate will remain stable during printing and storage. This post-exposure step utilizes the same radiation source as the main exposure. Detackification is an optional post-development treatment which can be applied if the surface is still tacky, such tackiness not generally being removed in post-exposure. Tackiness can be eliminated by methods well known in the art, such as treatment with bromine or chlorine solutions. Such treatments have been disclosed in, for example, Gruetzmacher U.S. Pat. No. 4,400,459, Fickes et al., U.S. Pat. No. 4,400,460 and German Patent 28 23 300. Detackiiication can also be accomplished by exposure to radiation sources having a wavelength not longer than 300 nm, as disclosed in European Published Patent Application 0 017927 and Gibson U.S. Pat. No. 4,806,506. These elements can be used to particular advantage in the formation of seamless, continuous printing elements. The photopolymerizable flat sheet elements can be reprocessed by wrapping the element around a cylindrical form, usually a printing sleeve or the printing cylinder itself, and fusing the edges together to form a seamless, continuous element. In a preferred method, the photopolymerizable layer is wrapped around the cylindrical form and the edges joined. One process for joining the edges has been disclosed in German patent DE 28 44 426. The photopolymerizable layer can then be spray coated with the infrared-sensitive layer. Continuous printing elements have applications in the flexographic printing of continuous designs such as in wallpaper, decoration and gift wrapping paper. Furthermore, such continuous printing elements are well-suited for mounting on conventional laser equipment. The sleeve or cylinder on which the printing element is wrapped when the edges are fused, can be mounted directly into the laser apparatus where it functions as the rotating drum during the laser exposure step. Unless otherwise indicated, the term “flexographic printing plate or element” encompasses plates or elements in any form suitable for flexographic printing, including, but not limited to, flat sheets and seamless continuous forms. All publications/references mentioned herein are hereby incorporated by reference unless otherwise indicated. The following examples are provided to illustrate the practice of this invention and not to limit it in any manner. Unless otherwise noted percentages are by weight.

### EXAMPLES

Materials used in the following examples are available from standard commercial sources such as Aldrich Chemical Co. (Milwaukee, Wis.) unless otherwise specified. Silver behenate homogenates may be prepared as disclosed in U.S. Pat. No. 4,210,717 or U.S. Pat. No. 3,457,075.

### Example 1

The following solutions were prepared Silver Emulsion: A. Silver containing solution was made up as follows:

| | |
|---|---|
| Silver behenate | 4.56 |
| Butvar ™ B76 poly(vinyl butyral), available from | 2.28 |
| Monsanto Co. | |
| Dodecyl sodium sulfate | 0.08 |
| Butanol | 61.48 |

B. Activator Solution: An activator coating solution comprising the following ingredients (parts by weight) was prepared:

| | |
|---|---|
| Gallic Acid | 1.52 |
| Dodecyl sodium sulfate | 0.08 |
| Benzotriazole | 0.16 |
| PINA KF1085 (an infrared absorbing dye) | 0.12 |
| Ethanol | 10.00 |
| Butanol | 31.60 |

6.84 g of part A and 3.16 g of part B were well mixed and coated with a #60 coater rod onto a piece of Cyrel™ PQS flexographic printing plate (available from DuPont de Nemours) from which the Mylar™ coversheet had been removed. The coating was exposed using a Creo Products Inc. laser diode imaging device operating at 830 nm 40 mW per channel and a 6.4 micron spot using a drum speed to obtain 400 mJ/square cm to produce an image in the thermographic layer. The resultant material was given a back flash of 14 seconds followed by an imaging exposure for 10 minutes using a (Kelleigh Corp.) exposure development machine. The plate was developed in Optiso™ (a commercially available developer from DuPont) for 20 minutes and dried for 1 hour at 140C. This produced a plate with a good image.

### Example 2

Solutions similar to those in example 1 were prepared except that the infra-red absorbing dye is ADS 830A (available from American Dye Source Inc.) A good plate was prepared using similar coating, exposure and development conditions to those in Example 1.

### Example 3

In this example, a similar coating was used as in Example 1 except 3,4-dihydroxybenzoic acid was used as reducing agent in place of gallic acid. A similar result was obtained from the finished plate.

### Example 4

In this example the construction of the invention was compared with a sample of flexographic plate produced using a process-less film phototool (Volcano™ from Kodak Inc) with Cyrel™ DPS (DuPont ablative flexographic plate) and with a carbon filled ablative layer without a barrier layer. The flexographic plate used was Cyrel™ PLS (from DuPont) except for the commercially available digitally exposed ablative plate (DPS). The infra-red absorbing layers were exposed to produce images and the resultant flexographic plates exposed, developed, dried and finished using the conditions found for example 1. The appearance of the plates was noted and is shown in Table 1. The plate samples were then printed on a Mark Andy Model 2000 label press using Akzo Nobel™ UV curable black ink on coated paper. The press was run for 1000 impressions at an ink density of about 1.3 without signs of wear, and measurements were made of the dots. These results are shown in Table 2.

TABLE 1

| Plate | Highlight Dots | | Shadow Dots | |
|---|---|---|---|---|
| Thermal Integral mask | 2% | resolved | 98% | open |
| | 1 | pt type open | | |
| Cyrel ™ DPS | 2% | missing | 98% | open |
| | 3-5% | deformed | | |
| Carbon black ablated | 2% | missing | 98% | open |
| | 3-4% | deformed | | |
| | 5% | resolved | | |
| Cyrel ™ PLS with processless | 3% | resolved | 96% | open |
| Phototool | | | 98% | closed |

TABLE 2

| | | |
|---|---|---|
| % Dot | Measured Dot | Description |

Cyrel ™ DPS

| | | |
|---|---|---|
| <4% | | No print |
| | | 1 pt type printed |
| 5% | 1% | Faint partial dots |
| 10% | 19% | |
| 50% | 71% | |
| 90% | 95% | |
| 98% | 98% | |

Cyrel ™ PLS with phototool

| | | |
|---|---|---|
| 2% | 22% | 1 pt type blurred |
| 3% | 26% | |
| 5% | 32% | |
| 50% | 85% | |
| 90% | 99% | Looks closed |
| 98% | 100% | |

Carbon black ablated

| | | |
|---|---|---|
| 2% | | No dots |
| | | 1 pt type printed |
| 3% | 12% | Partial dots |
| 5% | 21% | Resolved |
| 10% | 21% | |
| 50% | 77% | |
| 90% | 97% | |
| 98% | 100% | Closed |

Thermal integral mask

| | | |
|---|---|---|
| 2% | 4% | Damaged dots |
| | | 1 pt type printed |
| 3% | 8% | Well resolved |
| 5% | 14% | |
| 10% | 24% | |
| 50% | 75% | |
| 90% | 96% | |
| 98% | 98% | |

The results show the superior dot characteristics of the thermal integral mask over the existing technologies. It is possible to hold smaller dots without damage. This is a result that could not have been predicted from the knowledge of the prior art.

The foregoing specification and examples provide a description of the invention. Reasonable variations and modifications are possible from the foregoing disclosure without departing from either the spirit or scope of the present invention, which resides in the claims appended hereto.

In addition to the manufacture of a flexographic plate, the integral mask of the invention could be used in the production of gravure plates. In this embodiment, the substrate may be copper and a resist then integral mask is coated thereon. The integral mask is digitally imaged, then the resist is imaged through the mask. Then the integral mask is removed, and the portions of the resist that may now be removed to form the gravure image are removed. Then the copper is etched through the resist and the remaining resist is or may be removed.

The substrate may be any material with a photopolymer therein, the process is performed as described above, and the remaining photopolymer becomes the gravure cylinder surface.

What is claimed:

1. A photosensitive printing element for preparing flexographic printing plates comprising at least the following layers in the order of:
(a) a support,
(b) a photopolymerizable layer comprising an elastomeric composition sensitive to non-infrared actinic radiation, said layer being soluble, swellable or dispersible in a liquid developer prior to exposure to said non-infrared actinic radiation,
(c) at least one layer comprising an infrared radiation sensitive thermographic material which provides increased image density at the wavelengths in the electromagnetic region of said non-infrared radiation sensitivity upon exposure to infrared laser radiation sufficient to prevent polymerization of the layer (b) during the U.V. exposure.

2. The photosensitive printing element of claim 1 wherein the infrared radiation sensitive thermographic material provides image density of greater than 3.0 at the wavelengths in the electromagnetic region of said non-infrared radiation sensitivity upon exposure to infrared laser radiation.

3. The photosensitive element of claim 1 wherein said (c) at least one layer provides an image density of at least 3.0 when exposed to infrared radiation between 750 and 850 nm at a fluence of 1.0 Joules/cm² for less than 1 minute.

4. The photosensitive element of claim 1 wherein layer (c) comprises a thermographic layer comprising a binder, a light-insensitive reducible silver source, and a reducing agent for silver ion.

5. The photosensitive element of claim 2 wherein layer (c) comprises a thermographic layer comprising a binder, a light-insensitive reducible silver source, and a reducing agent for silver ion.

6. The photosensitive element of claim 4 wherein said reducible silver source comprises a silver salt of a fatty acid.

7. The photosensitive element of claim 5 wherein said reducible silver source comprises a silver salt of a fatty acid.

8. A photosensitive printing element for preparing flexographic printing plates comprising in order:
(a) a flexible support,
(b) a photopolymerizable layer comprising an elastomeric composition sensitive to non-infrared actinic radiation, said layer being soluble, swellable or dispersible in a liquid developer prior to exposure to said non-infrared actinic radiation,
(c) at least one layer comprising a thermographically imageable material that provides image density greater than 3.0 at the wavelengths in the electromagnetic region of said non-infrared radiation sensitivity upon exposure to infrared laser radiation.

9. The photosensitive printing element of claim 4 wherein layer (c) is removable from layer (b) by washing with said liquid developer and scrubbing.

10. A process for providing a flexible printing plate with a printing image thereon comprising:
imagewise exposing the photosensitive printing element of claim 1 to an infrared radiation source of sufficient intensity to generate an image in layer (c) having a maximum optical density sufficient to slow or prevent polymerization of the photosensitive elastomeric layer, forming a mask image in layer (c);
exposing layer (b) with radiation that passes through imagewise areas of layer (c) that allows transmission of said non-infrared actinic radiation, and altering the solubility or dispersibility of layer (b) with respect to said liquid developer; and
developing said photosensitive printing element to form a printable image in layer (b) on said flexible substrate.

11. A process for providing a flexible printing plate with a printing image thereon comprising:
imagewise exposing the photosensitive printing element of claim 1 to an infrared radiation source of sufficient intensity to generate an image in layer (c) having a maximum optical density of at least 2.5, forming a mask image in layer (c);
exposing layer (b) with radiation that passes through imagewise areas of layer (c) that allows transmission of said non-infrared actinic radiation, and altering the solubility or dispersibility of layer (b) with respect to said liquid developer; and
developing said photosensitive printing element to form a printable image in layer (b) on said flexible substrate.

12. The process of claim 10, wherein at least portions of layer (c) with an image thereon is removed from layer (b) after said exposing layer (b) but before developing said photosensitive printing element.

13. The process of claim 10, wherein at least portions of layer (c) with an image thereon is removed from layer (b) at the same time as developing said photosensitive printing element.

14. The process of claim 10, wherein at least portions of layer (c) with an image thereon is removed from layer (b) by the liquid developer at the same time that the liquid developer is used on layer (b).

15. The process of claim 10 wherein only portions of layer (c) are removed from layer (b).

16. A photosensitive printing element for preparing flexographic printing plates comprising at least the following layers in the order of:
(a) a flexible support,
(b) a photopolymerizable layer comprising an elastomeric composition sensitive to non-infrared actinic radiation, said layer being soluble, swellable or dispersible in a liquid developer prior to exposure to said non-infrared actinic radiation or absorbable in a porous medium when heated,
(c) at least one layer comprising an infrared radiation sensitive thermographic material which provides image density greater than 3.0 at the wavelengths in the electromagnetic region of said non-infrared radiation sensitivity upon exposure to infrared laser radiation.

17. A backside exposable photosensitive printing element for preparing flexographic printing plates comprising at least three layers in the orders of:
(A) (a) a transparent flexible support,
(b) at least one layer comprising a thermographically imageable material that provides image density sufficient to prevent polymerization of the photopolymerizable composition at the wavelengths in the electromagnetic region of said non-infrared radiation sensitivity upon exposure to infrared laser radiation.
(c) a photopolymerizable layer comprising an elastomeric composition sensitive to non-infrared actinic radiation, said layer being soluble, swellable or dispersible in a liquid developer prior to exposure to said non-infrared actinic radiation; or
(B) (d) a photopolymerizable layer comprising an elastomeric composition sensitive to non-infrared actinic radiation, said layer being soluble, swellable or dispersible in a liquid developer prior to exposure to said non-infrared actinic radiation
(e) a transparent flexible support,
(f) at least one layer comprising a thermographically imageable material that provides image density greater than 3.0 at the wavelengths in the electromagnetic region of said non-infrared radiation sensitivity upon exposure to infrared laser radiation.

18. A backside exposable photosensitive printing element for preparing flexographic printing plates comprising at least three layers in the orders of:
(A) (a) a transparent flexible support,
(b) at least one layer comprising a thermographically imageable material that provides image density greater than 2.5 at the wavelengths in the electromagnetic region of said non-infrared radiation sensitivity upon exposure to infrared laser radiation.
(c) a photopolymerizable layer comprising an elastomeric composition sensitive to non-infrared actinic radiation, said layer being soluble, swellable or dispersible in a liquid developer prior to exposure to said non-infrared actinic radiation; or
(B) (d) a photopolymerizable layer comprising an elastomeric composition sensitive to non-infrared actinic radiation, said layer being soluble, swellable or dispersible in a liquid developer prior to exposure to said non-infrared actinic radiation
(e) a transparent flexible support,
(f) at least one layer comprising a thermographically imageable material that provides image density greater than 2.5 at the wavelengths in the electromagnetic region of said non-infrared radiation sensitivity upon exposure to infrared laser radiation.

19. A method for the manufacture of the photosensitive printing element of claim 1 comprising providing a flexographic printing element and coating
at least one layer comprising an infrared radiation sensitive thermographic material which provides increased image density at the wavelengths in the electromagnetic region of said non-infrared radiation sensitivity upon exposure to infrared laser radiation sufficient to prevent polymerization of a photosensitive component in the flexographic printing element during U.V. exposure onto an image-developable surface of the flexographic printing element.

20. The process of claim 19 wherein the image-developable surface of the flexographic printing element comprises an elastomeric composition sensitive to non-infrared actinic radiation, said layer being soluble, swellable or dispersible in a liquid developer prior to exposure to said non-infrared actinic radiation.

21. A process for manufacture of a gravure printing surface comprising the steps of providing a gravure printing surface having a photosensitive resist material coated on a surface of a support, coating
at least one layer comprising an infrared radiation sensitive thermographic material which provides increased image density at the wavelengths in the electromagnetic region of said non-infrared radiation sensitivity upon exposure to infrared laser radiation sufficient to prevent polymerization of a photosensitive component in the flexographic printing element during U.V. exposure over the photosensitive resist material coated on the surface of the support, imaging the at least one layer with infrared radiation to provide a mask image, exposing the photosensitive resist material through the mask image, and removing the mask image to form the gravure image.

22. The process of claim 21 wherein the photoresist is developed to remove photoresist material to form a gravure image.

23. The process of claim 22 wherein the surface of the support is metal and the metal is etched through the resist to form a gravure printing surface.
